(19) United States
(12) Patent Application Publication
(10) Pub. No.: US 2009/0090974 A1
(43) Pub. Date: Apr. 9, 2009

(54) DUAL STRESS LINER STRUCTURE HAVING SUBSTANTIALLY PLANAR INTERFACE BETWEEN LINERS AND RELATED METHOD

(75) Inventors: Gregory Costrini, Hopewell Junction, NY (US); David M. Fried, Brewster, NY (US); Werner A. Rausch, Stormville, NY (US); Christopher D. Sheraw, Poughkeepsie, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/868,567

(22) Filed: Oct. 8, 2007

(51) Int. Cl. H01L 27/092; H01L 21/311

(52) U.S. Cl. 257/369; 438/694; 257/E27.062; 257/E21.249

(57) ABSTRACT

A dual stress liner structure having a substantially planar interface between liners and a related method are disclosed. In one embodiment, a dual stress liner structure may include a tensile stress liner over an NFET, the NFET including a PFET adjacent thereto; and a compressive stress liner over the PFET, wherein an upper surface of the compressive stress liner is substantially planar with an upper surface of the tensile stress liner at an interface therebetween.

### BACKGROUND

1. Technical Field

The disclosure relates generally to integrated circuit (IC) fabrication, and more particularly, to a dual stress liner and a related method.

2. Background Art

The application of stresses to field effect transistors (FETs) is known to improve their performance. When applied in a longitudinal direction (i.e., in the direction of current flow), tensile stress is known to enhance electron mobility (or n-channel FET (NFET) drive currents) while compressive stress is known to enhance hole mobility (or p-channel FET (PFET) drive currents). One way to apply such stresses to a FET is the use of intrinsically-stressed barrier silicon nitride liners. For example, a tensile-stressed silicon nitride liner may be used to cause tension in an NFET channel while a compressively-stressed silicon nitride liner may be used to cause compression in a PFET channel. Accordingly, a dual stressed liner (DSL) scheme is necessary to induce the desired stresses in an adjacent NFET and PFET.

One challenge relative to forming a DSL, as shown in FIG. 1, is that a compressive stress liner extension 10 overlaps onto and above the adjacent tensile stress liner 12 following dual stress liner formation. In an alternative approach, the compressive stress liner is deposited prior to the tensile stress liner. The same overlap extension results from that integration sequence, although the tensile stress liner would extend over the compressive stress liner. This feature poses potential yield issues in middle-of-line (MOL) contact and first metal formation. For example, for 45 nm technology, the stress nitride liner overlap extension 10 reaches the bottom of the first metal features and may cause topography issues with oxide and contact planarization. In addition, the liner overlap will laterally encroach into contact 14 space with the potential for open or high resistance contacts. Furthermore, modeling of the stress applied to the devices indicates that the restriction of the stress nitride to the respective regions maximizes the applied stress to the devices. Current solutions utilize a reactive ion etch (RIE) overetch with lithography biasing, which offers limited relief due to the inherent lithography tolerance and RIE selectivity limitations.

### SUMMARY

A dual stress liner structure having a substantially planar interface between liners and a related method are disclosed. In one embodiment, a dual stress liner structure may include a tensile stress liner over an NFET, the NFET including a PFET adjacent thereto; and a compressive stress liner over the PFET, wherein an upper surface of the compressive stress liner is substantially planar with an upper surface of the tensile stress liner at an interface therebetween.

A first aspect of the disclosure provides a method comprising: forming a tensile stress liner over an NFET, the NFET including a PFET adjacent thereto; depositing a compressive stress liner over the NFET and the PFET; forming a cap layer over the compressive stress liner; patterning the compressive stress liner and the cap layer such that the compressive stress liner remains over the PFET and extends above an upper surface of the tensile stress liner over the NFET; recessing the compressive stress liner under a remaining portion of the cap layer such that the compressive stress liner no longer extends substantially above or over the upper surface of the tensile stress liner; and removing the cap layer.

A second aspect of the disclosure provides a dual stress liner structure comprising: a tensile stress liner over an NFET, the NFET including a PFET adjacent thereto; and a compressive stress liner over the PFET, wherein an upper surface of the compressive stress liner is substantially planar with an upper surface of the tensile stress liner at an interface therebetween.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a conventional dual stress liner structure.

FIGS. 2-5 show embodiments of a method according to the disclosure with FIG. 5 showing embodiments of a dual stress liner structure according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

Turning to FIGS. 2-5, embodiments of a method according to the disclosure are illustrated. FIG. 2 shows initial structure including an n-type field effect transistor (NFET) 102 (two shown) adjacent to a p-type field effect transistor (PFET) 104. As the formation of these structures is well known in the art, further description of the process and structure formed will be omitted. FIG. 2 also shows forming a tensile stress liner 112 over NFET 102, e.g., by deposition of an intrinsic tensile-stressed silicon nitride (Si₃N₄) or other tensile-stressed liner material. “Depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

A cap layer 120 may be provided over tensile stress liner 112. Tensile stress liner 112 is also shown patterned to remove it from over PFET 104, which may occur in any now known or later developed manner, e.g., mask deposition, mask patterning and etching, and then etching of liner 112 using the mask. A reactive ion etch (RIE) may be used, for example.

FIG. 2 also shows depositing a compressive stress liner 114 over NFET 104 and PFET 102. Compressive stress liner 114 may include any intrinsic compressively-stressed silicon nitride (Si₃N₄) or other compressively-stressed liner material. In contrast to conventional approaches, a cap layer 130 is formed over compressive stress liner 114, e.g., by deposition of material. Cap layer 130 may include silicon oxide (SiO₂), a glass or any dielectric film exhibiting etch selectivity to stress liners 112, 114.

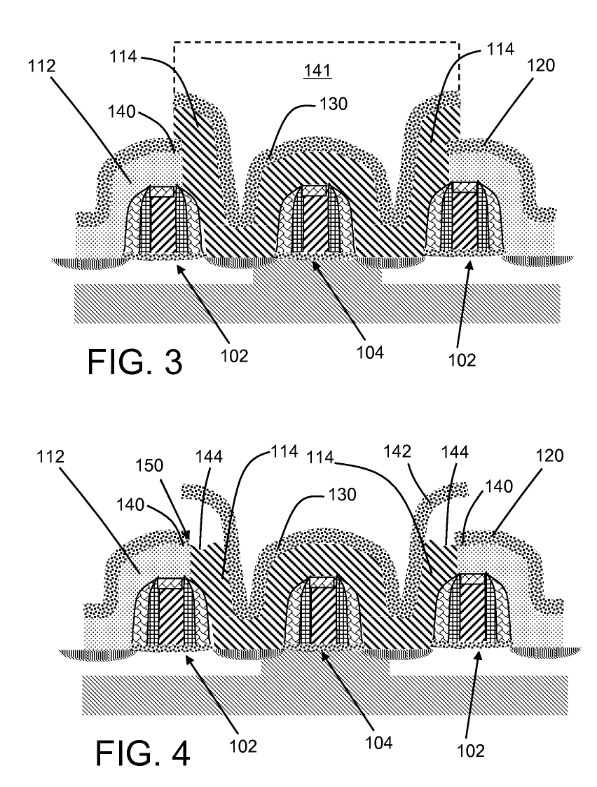

FIG. 3 shows patterning compressive stressed liner 114 and cap layer 130 such that compressively stressed liner 114 remains over PFET 104 and extends above an upper surface 140 of tensile stressed liner 112 over NFET 102. This process may be completed using any known or subsequently developed photolithography technique, e.g., depositing a mask 141, patterning and etching the mask and etching compressively stressed liner 114 and cap layer 130. A reactive ion etch (RIE) may be used, for example.

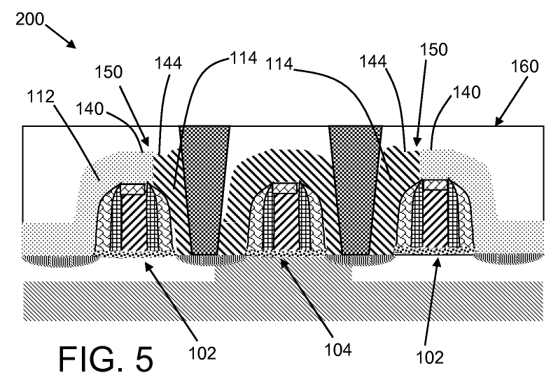

FIG. 4 shows recessing (also referred to as pullback) of compressively stressed liner 114 (exposed edge thereof), under a remaining portion 142 of cap layer 130, such that compressively stressed liner 114 no longer extends substantially above or over upper surface 140 of tensile stressed liner 112. The recessing may be accomplished by performing a selective wet etch such as hot phosphoric acid. As illustrated, the recessing is controlled such that no voids or gaps are formed at the interface between the compressive stress liner 114 and tensile stressed liner 112. Furthermore, the recessing may not have uniform re-entry of compressive stress liner 114. However, recessing results in an upper surface 144 of compressively stressed liner 114 that is substantially planar with upper surface 140 of tensilely stressed liner 112 at an interface 150 therebetween. That is, compressive stress liner 114 neither extends substantially above tensile stressed liner 112 or over tensile stressed liner 112. No gaps are formed at the interface between stress liners 112, 114.

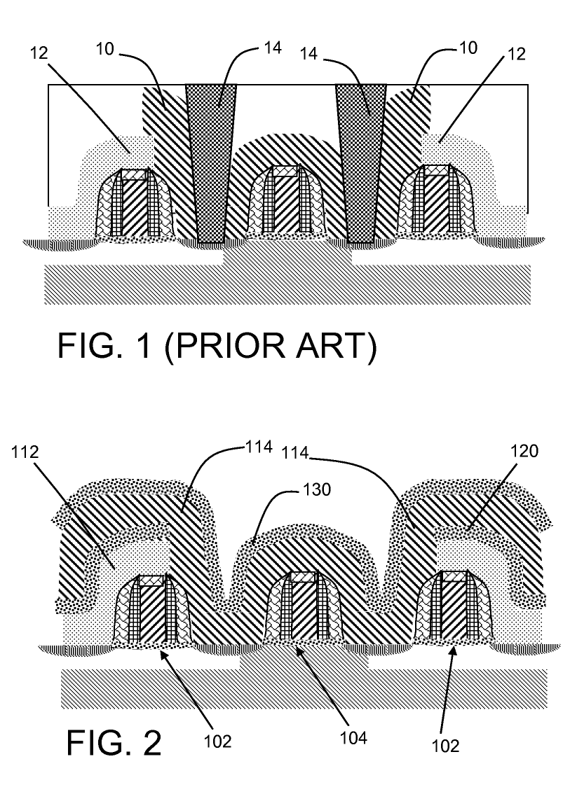

FIG. 5 shows a dual stress liner structure 200 according to the disclosure after removal of cap layers 120, 130 (FIG. 4) using, for example, RIE. A back-end-of-line layer 160 may also be formed over compressively stressed liner 114 and tensilely stressed liner 112 using any now known or later developed techniques, e.g., dielectric deposition, patterning and etching, deposition of a metal into contact openings and planarization. The above-described methods, inter alia, reduce the extension 10 (FIG. 1) of compressive stress liner at the DSL interface 150 with potential for substantial MOL yield improvement by improving planarization, reducing open contacts, and restricting the liners to the respective regions to maximize the applied stress.

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method comprising:
forming a tensile stress liner over an NFET, the NFET including a PFET adjacent thereto;
depositing a compressive stress liner over the NFET and the PFET;
forming a cap layer over the compressive stress liner;
patterning the compressive stress liner and the cap layer such that the compressive stress liner remains over the PFET and extends above an upper surface of the tensile stress liner over the NFET;
recessing the compressive stress liner under a remaining portion of the cap layer such that the compressive stress liner no longer extends above or over the upper surface of the tensile stress liner; and
removing the cap layer.

2. The method of claim 1, wherein the recessing includes performing a selective wet etch.

3. The method of claim 1, wherein the cap layer is selected from the group consisting of: silicon oxide and a glass.

4. The method of claim 1, wherein the compressive stress liner and the tensile stress liner include silicon nitride (Si₃N₄).

5. The method of claim 1, further comprising forming a back-end-of-line layer over the compressive stress liner and the tensile stress liner.

6. A dual stress liner structure comprising:
a tensile stress liner over an NFET, the NFET including a PFET adjacent thereto; and
a compressive stress liner over the PFET, wherein an upper surface of the compressive stress liner is substantially planar with an upper surface of the tensile stress liner at an interface therebetween.

7. The structure of claim 6, wherein the compressive stress liner and the tensile stress liner include silicon nitride (Si₃N₄).
